(19) United States
(12) Patent Application Publication
(10) Pub. No.: US 2024/0128080 A1
(43) Pub. Date: Apr. 18, 2024

(54) COMPOUND SEMICONDUCTOR LAYERED STRUCTURE AND PROCESS FOR PREPARING THE SAME

(71) Applicant: UMICORE, Brussel (BE)

(72) Inventors: Markus LEITGEB, Vienna (AT); Ben DEPUYDT, Brussels (BE); Georg PFUSTERSCHMIED, Vienna (AT); Ulrich SCHMID, Vienna (AT)

(21) Appl. No.: 18/277,564

(22) PCT Filed: Feb. 28, 2022
(86) PCT No.: PCT/EP2022/054964

§ 371 Date: Aug. 16, 2023

(30) Foreign Application Priority Data
Mar. 1, 2021 (EP) 21159944.4
May 4, 2021 (EP) 21171992.7
Nov. 18, 2021 (EP) 21209102.9

(51) Int. Cl. H01L 21/02; H01L 21/04; H01L 23/14

(52) U.S. Cl. CPC H01L 21/02529; H01L 21/02378; H01L 21/0262; H01L 21/02664; H01L 21/0445; H01L 23/147

(57) ABSTRACT

The present invention provides compound semiconductor layered structures comprising a semiconductor substrate having a bottom layer and a top layer; and a semiconductor film on top of said semiconductor substrate, said semiconductor film comprising a bottom layer, a core and a top layer, whereby said bottom layer of said semiconductor film is in contact with said top surface of said semiconductor substrate, and wherein said top layer is nonporous. Preferred compound semiconductors further comprise a semiconductor overlayer having a bottom surface layer and a top surface layer, whereby said bottom surface layer of said second semiconductor layer is in contact with said top layer of said semiconductor film. The present invention also provides process for preparing the same.

### TECHNICAL FIELD

The present invention relates to novel substrates for preparing compound semiconductor devices and methods for making the same. Specifically, the present invention relates to silicon carbide semiconductors.

### INTRODUCTION

Silicon carbide emerges as a most promising alternative to silicon as semiconductor material, especially for power electronic devices. This is due to its unique material properties, such as wide electronic bandgap and high thermal conductivity. However, in spite of tremendous progress, over the last decades, in both material quality and device manufacturing, widespread adoption is still hampered by the high cost of monocrystalline silicon carbide substrates. The main factors contributing to that high cost are the crystal growth process, the subsequent ingot slicing and the polishing of the substrates.

U.S. Pat. No. 9,738,991 B2 discloses a method of forming a silicon carbide crystal, the method including: placing a silicon carbide seed in a growth vessel, heating the growth vessel, and evacuating the growth vessel, wherein the seed is levitated as a result of a temperature and pressure gradient, and gas flows from a growth face of the seed, around the edge of the seed, and into a volume behind the seed, which is pumped by a vacuum system.

More recently, Leitgeb, M. et al. J. Electrochem. Soc. 2017, 164 (12), E337, described novel methods for preparing porous 4H-SiC layers from monocrystalline samples applying photo-electrochemical etching in hydrofluoric acid. It was found that the resulting degree of porosity, the homogeneity in porosity as well as the pore morphology mainly depend on the applied voltage. Importantly, the approach allowed to detach the porous 4H—SiC layers, which comprised several sub-layers of alternating degree of porosity, from the 4H-SiC substrate.

Beside prior art related to the fabrication details of the invention, alternative routes for the detachment of a layer from a SiC substrate, and eventual subsequent bonding onto another substrate, are described in literature. In those approaches a line of breakage is created underneath the surface of the mother substrate by utilizing ion implantation. The generated line of breakage allows the mechanical separation of a thin layer from the mother substrate which can subsequently transferred to a polycrystalline substrate.

Present methods still rely on the use of a series of multiple, complex processing steps. As such they have poor materials economy and a nonnegligible environmental impact. The present invention aims to provide new methods for producing monocrystalline semiconductors, those methods allowing for economical use of starting materials, energy-efficiency and flexibility in production. More specifically, the current invention aims at a substantial reduction of the cost, improvement of energy footprint and reduction of waste material.

### SUMMARY

The current invention provides a solution for at least one of the above-mentioned problems by providing a compound semiconductor layered structure, as described in claim 1, and a process for preparing the same. In essence, the object of the invention is realized by repetitively detaching a layer from a single mother substrate, e.g. silicon carbide substrate, and bonding that layer to a relatively inexpensive but electronically compatible carrier substrate.

In a first aspect, the present invention provides a compound semiconductor layered structure comprising:
i. a semiconductor substrate having a bottom surface and a top surface; and
ii. a semiconductor film on top of said semiconductor substrate, said semiconductor film comprising a bottom layer, a porous core and a top layer, whereby said bottom layer of said semiconductor film is in contact with said top surface of said semiconductor substrate.

This is advantageous for providing a semiconductor film with desired composition and morphology, i.e. for growing a monocrystalline semiconductor layer onto said semiconductor film. This avoids the one-time use of a substrate material with high carbon dioxide footprint and allows for a material- and energy-economic process for preparing a semiconductor layer. Furthermore, dependence of the process on critical materials such as germanium or indium phosphorus may be decreased. Waste generation during to production process can be greatly reduced, resulting in an improved carbon dioxide footprint.

In a second aspect, the invention provides a process for preparing a compound semiconductor layered structure, whereby a porous semiconductor film in contact with a semiconductor substrate is subjected to a heat treatment at a temperature above 1200° C. to form a compound semiconductor layered structure.

In a third aspect, the present invention provides an electronic device for power electronics comprising a compound semiconductor layered structure according to the first aspect of the invention.

### DESCRIPTION OF THE FIGURES

By means of further guidance, figures are included to better appreciate the teaching of the present invention. Said figures are intended to assist the description of the invention and are nowhere intended as a limitation of the presently disclosed invention.

The figures and symbols contained therein have the meaning as commonly understood by one of ordinary skill in the art to which this invention belongs.

FIG. 1 schematically shows a cross-section of a compound semiconductor layered structure according to the invention, said compound semiconductor comprising a semiconductor substrate 1 and a semiconductor film 2 having a core 22 on top of said semiconductor substrate 1.

FIG. 2 schematically shows a cross-section of a compound semiconductor layered structure according to the invention, said compound semiconductor further comprising a semiconductor layer 3 on top of said semiconductor film 2.

FIG. 3 shows a cross-sectional SEM image of a porous, single-crystalline layer with special porosity profile including step function on top and bottom side of the layer.

FIG. 4 shows a cross-sectional SEM image of a porous layer on top of a single-crystalline 4H—SiC after heat treatment.

FIG. 5 shows a cross-sectional SEM micrograph of a porous 4H—SiC layer exhibiting a step-like decrease of porosity introduced by changing the applied voltage during PECE from 11.5 Volt to 8.5 Volt.

FIG. 6 shows a cross-sectional SEM micrograph showing the reorganization of a porous layer depicted in FIG. 5 after annealing at 1600° C.

### DETAILED DESCRIPTION OF THE INVENTION

Unless otherwise defined, all terms used in disclosing the invention, including technical and scientific terms, have the meaning as commonly understood by one of ordinary skill in the art to which this invention belongs. By means of further guidance, term definitions are included to better appreciate the teaching of the present invention.

As used herein, the following terms have the following meanings:

“A”, “an”, and “the” as used herein refers to both singular and plural referents unless the context clearly dictates otherwise. By way of example, “a compartment” refers to one or more than one compartment.

“About” as used herein referring to a measurable value such as a parameter, an amount, a temporal duration, and the like, is considered synonymous to the term “substantially” and is meant to encompass variations of +/−20% or less, preferably +/−10% or less, more preferably +/−5% or less, even more preferably +/−1% or less, and still more preferably +/−0.1% or less of and from the specified value, in so far such variations are appropriate to perform in the disclosed invention. However, it is to be understood that the value to which the modifier “about” refers is itself also specifically disclosed.

“Comprise,” “comprising,” and “comprises” and “comprised of” as used herein are synonymous with “include”, “including”, “includes” or “contain”, “containing”, “contains” and are inclusive or open-ended terms that specifies the presence of what follows e.g. component and do not exclude or preclude the presence of additional, non-recited components, features, element, members, steps, known in the art or disclosed therein.

The recitation of numerical ranges by endpoints includes all numbers and fractions subsumed within that range, as well as the recited endpoints. All percentages are to be understood as percentage by weight, abbreviated as “wt. %” or as volume percent, abbreviated as “vol. %”, unless otherwise defined or unless a different meaning is obvious to the person skilled in the art from its use and in the context wherein it is used.

The term “semiconductor” refers to any solid substance that has an electrical conductivity between that of an insulator and that of most metals. An example semiconductor layer is composed of silicon. The semiconductor layer may include a single bulk wafer, or multiple sublayers. Specifically, a semiconductor layer and more preferably a silicon carbide semiconductor layer may include multiple non-continuous porous portions. The multiple non-continuous porous portions may have different densities and may be horizontally distributed or vertically layered. Examples of semiconductor materials include, without limitation, alumina, silicon carbide, gallium-arsenide, indium-phosphide, silica, silicon dioxide, borosilicate glass, pyrex, and sapphire.

In the context of the present invention, a compound semiconductor is a semiconductor composed of chemical elements of at least two different species, such as Group III and V elements and Group II and VI elements. These semiconductors typically form in periodic table groups 13-15 (old groups III-V), for example of elements from the Boron group (old group III, boron, aluminium, gallium, indium) and from group (old group V, nitrogen, phosphorus, arsenic, antimony, bismuth). The range of possible formulae is quite broad because these elements can form binary (two elements, e.g. gallium (III) arsenide (GaAs)), ternary (three elements, e.g. indium gallium arsenide (InGaAs)) and quaternary (four elements, e.g. aluminium gallium indium phosphide (AlInGaP)) alloys. GaAs, InP and InGaAIP are used for their application for high-frequency devices and optoelectronic devices. SiC and GaN compound semiconductors are often employed for power semiconductors. Typical compound semiconductors are:
Group II-VI: ZnSe
Group III-V: GaAs, GaN, InP, InGaAIP, InGaN
Group IV-IV: SiC, SiGe

In the context of the present invention, the term “substrate” or “semiconductor substrate” refers to a material consisting of a semiconductor material, specifically of a compound semiconductor material and more specifically silicon carbide, onto which deposited layers of a material may be formed or applied. Preferably, the substrate is a single-crystalline substrate. Said semiconductor substrate may also be referred to as a slice, a substrate or a wafer and are known to the person skilled in the art. Such semiconductor substrates are typically used as a substrate onto which microelectronic devices can be built. Semiconductor substrates may be subjected to different processes such as doping, ion implantation, etching, thin-film deposition or lithographic patterning. Exemplary substrates include, without limitation: bulk germanium wafers, bulk silicon wafers, in which a wafer comprises a homogeneous thickness of single-crystal silicon or germanium; composite semiconductor wafers comprising a homogeneous thickness of a mono- or polycrystalline compound semiconductor material; composite wafers, such as a silicon-on-insulator wafer that comprises a layer of silicon that is disposed on a layer of silicon dioxide that is disposed on a bulk silicon handle wafer; or the porous germanium, germanium over oxide and silicon, germanium over silicon, patterned germanium, germanium tin over germanium, and/or the like; or any other material that serves as base layer upon which, or in which, devices are formed. Preferably, said semiconductor substrate comprises silicon carbide. More preferably, said semiconductor substrate consists essentially of silicon carbide. A substrate may have a single bulk wafer, or multiple sublayers. Specifically, a substrate (e.g., silicon, germanium, etc.) may include multiple non-continuous porous portions. The multiple non-continuous porous portions may have different densities and may be horizontally distributed or vertically layered. In the context of the present invention, the term “substrate” generally refers to a material having a thickness of at least 1 μm. Semiconductor substrates generally have a cylindrical form whereby the diameter of said cylinder is referred to as the wafer size and the height of said cylinder is referred to as the wafer thickness. Semiconductor substrates as used in the context of the present invention may have a wafer size of 1-inch (25 mm) and having a thickness of typically around 275 μm; a wafer size of 2-inch (51 mm) and having a thickness of typically around 275 μm; a wafer size of 3-inch (76 mm) and having a thickness of typically around 375 μm; a wafer size of 4-inch (100 mm) and having a thickness of typically around 525 μm; a wafer size of 5-inch (125 mm) and having a thickness of typically around 625 μm; a wafer size of 6-inch (150 mm) and having a thickness of typically around 675 μm; a wafer size of 8-inch (200 mm) and having a thickness of typically around 725 μm; a wafer size of 12-inch (300 mm) and having a thickness of typically around 775 μm.

In the context of the present invention, the term “film” or “semiconductor film” refers to a semiconductor material having a substantially-uniform thickness of a material covering a surface. A film can have a porous or a nonporous structure. In the context of the present invention, the term “film” refers to a material having a thickness of 0.01 μm to 50 μm.

In the context of the present invention, the term “layer” or “semiconductor layer” refers to a semiconductor material having a substantially-uniform thickness of a material covering a surface. A layer can be either continuous or discontinuous (i.e., having gaps between regions of the material). For example, a layer can completely or partially cover a surface, or be segmented into discrete regions, which collectively define the layer (i.e., regions formed using selective-area epitaxy). Furthermore, a layer can have a porous or a nonporous structure. In the context of the present invention, the term “layer” refers to a material having a thickness of at least 0.1 μm and at most 800 μm. Also, in the context of the present invention, the term “core” is to be understood as synonymous to the term “core layer.”

A first layer or a first film described and/or depicted herein as “configured on,” “deposited on,” “on top of,” “on” or “over” a second layer or a second film can be immediately adjacent to the second layer, or one or more intervening layers can be between the first and second layers. In a preferred embodiment of the invention, said first layer or a first film is in direct contact with or bonded with or directly to said second layer or said second film. In the context of the present invention, the term “disposed on” means “exists on” an underlying material or layer. This layer may comprise intermediate layers, such as transitional layers, necessary to ensure a suitable surface. For example, if a material is described to be “disposed on a substrate,” this can mean either that the material is in intimate contact with the substrate; or that the material is in contact with one or more transitional layers that reside on the substrate.

In the context of the present invention, the term “in direct contact with” is synonymous for the terms “adhered directly to,” “bonded directly to,” “in direct contact with” and is to be understood as two distinct layers which may have the same composition, crystallinity, porosity but which are distinguishable, e.g. from cross-sectional SEM image analysis, by layer boundaries, whereby said two distinct layers are connected to each other or bonded to each other without use of a bonding agent such as an organic or inorganic gluing agent.

In the context of the present invention, the porosity of a material is expressed as volume percent, abbreviated as “vol. %” or as “%.” In the context of the present invention, porosity of a layer or a film can be determined by SEM analysis of said layer or film during multiple stages of an electrochemical etching process. SEM image analysis of a layer or film is obtained by etching with an electrolyte solution comprising 150 ml of 48 wt. % HF, 150 ml ethanol and 1200 ml deionized water in an etching chamber from AMMT GmbH for porous silicon etching and using a 250 Watt mercury arc lamp for front side illumination. The electrochemical etching process parameters used are (i) for C-face: 1 min 11.5V applied, 6 min 8.5 V applied, 1 min 11.5 V applied, 0.05 min 60 V applied for foil release from the substrate; and (ii) Si-face: 1 min 11.5V applied, 9 min 8.5 V applied, 1 min 11.5 V applied, 0.05 min 60 V applied for foil release from the substrate. The degree of porosity is analysed with an OpenCV image analysis library, using denoising and adaptive Gaussian image thresholding to determine the degree of porosity. In the context of the present invention, the term “porous” refers to a layer or film comprising pores, whereby the void volume of said layer or film is at least 1 vol. % of the total volume of said layer or film. Typically, the void volume of a porous layer is up to 30%, 40%, 50%, 60%, or even up to 70%. In the context of the present invention, the term “nonporous” refers to a layer or film preferably devoid of pores or a layer or film having a porosity of at most 1%, preferably at most 0.8%, more preferably at most 0.5% and most preferably 0%.

In the context of the present invention, the term “surface” refers to a two-dimensional outer face or exterior boundary of a body or part of a body, e.g. a layer; the term “surface area” refers to the size of said surface; and the term “surface layer” refers to a three-dimensional outer layer or exterior boundary of a body or part of a body, e.g. a layer. Hence, in the context of the present invention, the term ‘surface’ is distinguished from the term ‘surface area’ and from the term ‘surface layer.’

Any of the structures depicted and described herein can be part of larger structures with additional layers above and/or below those depicted. For clarity, the figures herein can omit these additional layers, although these additional layers can be part of the structures disclosed. In addition, the structures depicted can be repeated in units, even if this repetition is not depicted in the figures.

The growth and/or deposition described herein may be performed using one or more of chemical vapor deposition (CVD), metalorganic chemical vapor deposition (MOCVD), organometallic vapor phase epitaxy (OMVPE), atomic layer deposition (ALD), molecular beam epitaxy (MBE), halide vapor phase epitaxy (HYPE), pulsed laser deposition (PLD), and/or physical vapor deposition (PVD).

In a first aspect, the present invention provides a compound semiconductor layered structure comprising:
i. a semiconductor substrate having a bottom surface and a top surface; and
ii. a semiconductor film on top of said semiconductor substrate, said semiconductor film comprising a bottom layer, a core and a top layer, whereby said bottom layer of said semiconductor film is in contact with said top surface of said semiconductor substrate.

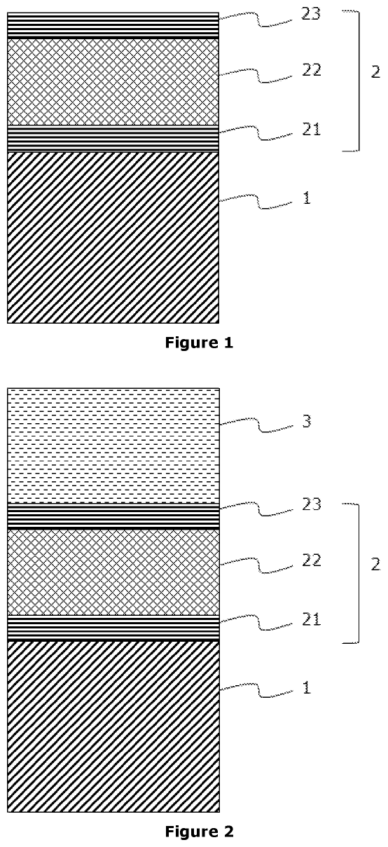

FIG. 1 schematically shows a cross-section of a compound semiconductor layered structure according to the invention, said compound semiconductor comprising a semiconductor substrate 1 and a semiconductor film 2 on top of said semiconductor substrate 1. The semiconductor film 2 comprises a bottom layer 21, a core 22 and a top layer 23.

Preferably, the present invention provides a compound semiconductor layered structure according to the first aspect of the invention, wherein said semiconductor substrate and said semiconductor film comprise a material selected from the group consisting of silicon carbide and gallium nitride. In a first embodiment, said semiconductor substrate and said semiconductor film comprise silicon carbide. Preferably, said silicon carbide comprises 4H-silicon carbide (4H—SiC). More preferably, said silicon carbide consists essentially of 4H-silicon carbide (4H—SiC). In a second embodiment, said semiconductor substrate and said semiconductor film comprise gallium nitride.

Preferably, the present invention provides a compound semiconductor layered structure according to the first aspect of the invention, wherein said top layer of said semiconductor film is nonporous. In other words, said top layer is impervious, dense, compact or closed. This is easily identified by SEM of a cross-section of said film. In case of a porous core, such top layer is characterized by an enhanced density relative to the density of the porous core. Preferably, said top layer of said semiconductor film is monocrystalline. Having a monocrystalline top layer allows for growing homoepitaxial layers directly on top of said top layer. In a first preferred embodiment, said bottom layer of said semiconductor film is porous and said top layer of said semiconductor film is nonporous. This is advantageous to allow for improved adhesion or binding to a polycrystalline substrate, e.g. a polycrystalline SiC substrate. In a second preferred embodiment, said bottom layer and said top layer of said semiconductor film are nonporous. This is easily identified by SEM of a cross-section of said film. In case of a porous core, such bottom layer and/or top layer are characterized by an enhanced density relative to the density of the porous core. Preferably, said bottom layer is monocrystalline.

A monocrystalline, porous compound semiconductor film can be obtained by an electrochemical porosification technique according to the experimental procedure described in Leitgeb, M. et al. Stacked Layers of Different Porosity in 4H SiC Substrates Applying a Photoelectrochemical Approach. J. Electrochem. Soc. 2017, 164 (12), E337, https://doi.org/10.1149/2.1081712jes; Leitgeb, M. et al. Metal Assisted Photochemical Etching of 4H Silicon Carbide. J. Phys. Appl. Phys. 2017, 50 (43), 435301, https://doi.org/10.1088/1361-6463/aa8942. The skilled person will appreciate that the porosity of the exfoliated compound semiconductor film can easily be modified by variation of the electrochemical process parameters. Ensuring that the surface layer of the exfoliated semiconductor film has a higher porosity compared to the core of said semiconductor film ensures optimal fusion bonding of the exfoliated semiconductor film onto said semiconductor substrate, as a result of compactification and migration of materials from areas of higher porosity to areas of lower porosity. Preferably, said exfoliated semiconductor film has a core portion having a porosity lower than 30%, and a surface layer portion having a porosity of higher than 30%. The inventors have further found that such an electrochemical porosification procedure maintains the crystallinity of the original semiconductor material.

Preferably, the present invention provides a compound semiconductor layered structure according to the first aspect of the invention, wherein said bottom layer and/or said top layer of said semiconductor film have a thickness of at least 1 nm, at least 2 nm, at least 5 nm, at least 10 nm, at least 15 nm, at least 20 nm or even at least nm, as determined by SEM image analysis. Said bottom layer and/or said top layer of said semiconductor film may have a thickness of 20 nm, 50 nm, 100 nm, 150 nm, 200 nm, 250 nm, 500 nm, 1000 nm or any thickness there in between. Optimized processing conditions may further allow for higher thickness of said bottom layer and/or top layer.

Preferably, said semiconductor film is in direct contact with said semiconductor substrate. More specifically, said bottom layer of said semiconductor film is in direct contact with said top surface of said semiconductor substrate. It may equally be said that said bottom layer of said semiconductor film is directly bonded or fusion bonded onto said top surface of said semiconductor substrate. The structure according to the first aspect of the invention provides the advantage that a semiconductor film with desired composition and morphology can be provided, i.e. for growing a semiconductor layer onto said semiconductor film, preferably for growing a monocrystalline semiconductor layer onto said semiconductor film. This allows for a process for preparing a semiconductor layer on top of a material- and energy-economic semiconductor substrate. By doing so, dependence on expensive and high carbon footprint bulk substrates is decreased. Waste generation during the production process can be greatly reduced, contributing to an improved carbon dioxide footprint. In a preferred embodiment, said semiconductor substrate is a compound semiconductor substrate. In a preferred embodiment, said semiconductor film is a compound semiconductor film.

A semiconductor film in direct contact with said semiconductor substrate may be obtained by direct bonding or fusion bonding. Direct bonding or fusion bonding is a well-established method of processing known to the skilled person in the field of semiconductor and compound semiconductor processing. It refers to a layer bonding process without any additional intermediate layers. The bonding consists essentially of chemical bonds between two surfaces which are sufficiently clean, flat, smooth and functionalized. The direct bonding or fusion bonding process generally consists of wafer pre-processing, pre-bonding at room temperature and annealing at elevated temperature.

Preferably, the present invention provides a compound semiconductor layered structure according to the first aspect of the invention, said compound semiconductor layered structure further comprising a semiconductor layer, also referred to as an overlayer, having a bottom surface and a top surface, whereby said bottom surface of said second semiconductor layer is in contact with said top layer of said semiconductor film. Preferably, said bottom surface of said second semiconductor layer is in direct contact with said top layer of said semiconductor film. The use of a semiconductor film of a predetermined quality on top of a semiconductor substrate of a different quality allows for the use of more readily available materials as substrate materials. In fact, whereas the semiconductor film is mainly chosen for the purposes of easily growing a semiconductor crystal layer on top of said film, the substrate may within the concept of the present invention, be selected mainly on the basis of mechanical and cost related characteristics, next to its thermo-mechanical and electrical compatibility with the semiconductor film on top of it. Said semiconductor overlayer comprises, without limitation, one or more selected of alumina, silicon carbide, gallium-arsenide, indium-phosphide, silica, silicon dioxide, borosilicate glass, pyrex, and sapphire. Preferably, said semiconductor overlayer comprises silicon carbide, and more preferably, said semiconductor overlayer consists essentially of silicon carbide. FIG. 2 schematically shows a cross-section of a compound semiconductor layered structure according to the invention, said compound semiconductor further comprising a semiconductor layer 3 on top of said semiconductor film 2.

In a preferred embodiment, said semiconductor layer is an epitaxially grown semiconductor layer, also referred to as an “overlayer.” In the context of the present invention, this means that the semiconductor layer is grown in a type of crystal growth or material deposition process in which new crystalline layers are formed with one or more well-defined orientations with respect to the crystalline semiconductor film. The deposited crystalline semiconductor layer is called an epitaxial layer. The relative orientation(s) of the epitaxial layer to the crystalline film is defined in terms of the orientation of the crystal lattice of each material. For epitaxial growth, the new layer must be crystalline and each crystallographic domain of the overlayer must have a well-defined orientation relative to the film crystal structure.

Preferably, the present invention provides a compound semiconductor layered structure according to the first aspect of the invention, wherein said semiconductor substrate comprises a polycrystalline material or an amorphous material. More preferably, said semiconductor substrate comprises a polycrystalline material. Preferably, said semiconductor substrate comprises the same compound material as the compound semiconductor film on top of said substrate. In an alternative and preferred embodiment, said semiconductor substrate comprises a silicon semiconductor material. This offers the advantage of good fusion between said semiconductor substrate and said semiconductor film, as well as good thermal and mechanical stability of the semiconductor substrate-film assembly.

Preferably, the present invention provides a compound semiconductor layered structure according to the first aspect of the invention, wherein said semiconductor film comprises a monocrystalline material. More specifically, the top layer of said semiconductor film has a monocrystalline structure, said top layer being nonporous. Said monocrystalline semiconductor film, more specifically said top layer of said film, provides a desirable seed layer for growing a monocrystalline semiconductor layer. The monocrystalline semiconductor layer, also referred to as overlayer, grown onto said top layer of said semiconductor film, is grown according to the crystallinity of the monocrystalline top layer.

In a specific embodiment of the invention, the present invention provides a compound semiconductor layered structure according to the first aspect of the invention, wherein said semiconductor film comprises a porous core. Preferably, said porous core of said semiconductor film has an average pore size of at most 500 nm, as determined by SEM image analysis. Preferably, said porous core of said semiconductor film has an average pore size of 50 nm to 500 nm, more preferably of 100 nm to 400 nm, and even more preferably of 150 nm to 350 nm. Most preferably said porous core of said semiconductor film has an average pore size of 160 nm, 170 nm, 180 nm, 190 nm, 200 nm, 210 nm, 220 nm, 230 nm or 240 nm, or any value there in between.

In a specific embodiment of the invention, the present invention provides a compound semiconductor layered structure according to the first aspect of the invention, wherein said semiconductor film comprises a porous core. Preferably, said porous core of said semiconductor film has a porosity of at most 50%, as determined by SEM image analysis. Said porous core of said semiconductor film may have a porosity of 1% to 40%, or of 5% to 35% and even of 10% to 30%, such as 10%, 15%, 20%, 25% or 30%, or any value there in between. Preferably, said porous core of said semiconductor film has a porosity of at most 40%, at most 30% or even at most 20%. Even more preferably, said porous core of said semiconductor film has a porosity of 15% or less, 12% or less or even 10% or less. SEM image analysis of a porous core is obtained by etching with an electrolyte solution comprising 150 ml of 48 wt. % HF, 150 ml ethanol and 1200 ml deionized water in an etching chamber from AMMT GmbH for porous silicon etching and using a 250 Watt mercury arc lamp for front side illumination. The electrochemical etching process parameters used are (i) for C-face: 1 min 11.5V applied, 6 min 8.5 V applied, 1 min 11.5 V applied, 0.05 min 60 V applied for foil release from the substrate; and (ii) Si-face: 1 min 11.5V applied, 9 min 8.5 V applied, 1 min 11.5 V applied, 0.05 min 60 V applied for foil release from the substrate. The degree of porosity is analysed with an OpenCV image analysis library, using denoising and adaptive Gaussian image thresholding to determine the degree of porosity.

Preferably, the present invention provides a compound semiconductor layered structure according to the first aspect of the invention, wherein said semiconductor film has a thickness of 0.05 to 100 μm, as determined by SEM image analysis, preferably of 0.05 to 75 μm, and more preferably of 0.05 to 50 μm. Preferably, the present invention provides a compound semiconductor layered structure according to the first aspect of the invention, wherein said semiconductor film has a thickness of 0.05 μm to 30 μm, as determined by SEM image analysis. Preferably, said semiconductor film has a thickness of 0.1 μm to 25 μm, more preferably of 0.5 μm to 16 μm, and even more preferably of 1 μm to 10 μm. Most preferably, said semiconductor film has a thickness of 1 μm to 5 μm, and especially preferred is equal to 1 μm, 2 μm, 3 μm, 4 μm or 5 μm, or any value there in between. Especially preferred, said semiconductor film has a thickness of 1 μm.

In a preferred embodiment, the present invention provides a compound semiconductor layered structure according to the first aspect of the invention, wherein said compound semiconductor layered structure has a diameter of 1 cm to 50 cm. More preferably, said compound semiconductor layered structure has a diameter of 5 cm to 35 cm. Most preferably, said diameter is about 100 mm or 4 inch, about 150 mm or 6 inch, about 200 mm or 8 inch, or about 300 mm or 12 inch, or any diameter there in between.

Preferably, the present invention provides a compound semiconductor layered structure according to the first aspect of the invention, wherein said semiconductor substrate comprises one or more materials selected from the group: gallium arsenide (GaAs), gallium nitride (GaN), silicon germanium (SiGe), silicon (Si) and silicon carbide (SiC). Preferably, said semiconductor substrate comprises silicon or silicon carbide, more preferably silicon carbide.

Preferably, the present invention provides a compound semiconductor layered structure according to the first aspect of the invention, wherein said semiconductor film comprises one or more materials selected from the group: gallium arsenide (GaAs), gallium nitride (GaN), silicon germanium (SiGe), silicon (Si) and silicon carbide (SiC). Preferably, said semiconductor film comprises silicon or silicon carbide, more preferably silicon carbide.

Preferably, the present invention provides a compound semiconductor layered structure according to the first aspect of the invention, wherein said semiconductor layer comprises one or more materials selected from the group: gallium arsenide (GaAs), gallium nitride (GaN), silicon germanium, (SiGe), and silicon carbide (SiC). Preferably, said semiconductor layer or overlayer comprises gallium nitride or silicon carbide, more preferably silicon carbide.

In a first preferred embodiment, the present invention provides a compound semiconductor layered structure according to the first aspect of the invention, wherein said semiconductor substrate layer, said semiconductor film, and if present said overlayer consist of SiC, preferably 4H—SiC.

In a second preferred embodiment, the present invention provides a compound semiconductor layered structure according to the first aspect of the invention, wherein said semiconductor substrate layer consists of AlN, said semiconductor film consists of GaN, and if present said overlayer consist of GaN.

In a third preferred embodiment, the present invention provides a compound semiconductor layered structure according to the first aspect of the invention, wherein said semiconductor substrate layer consists of a composite ceramic material, whereby said ceramic material has a coefficient of thermal expansion which is substantially matched to GaN, said semiconductor film consists of GaN, and if present said overlayer consist of GaN.

In a second aspect, the invention provides a process for preparing a compound semiconductor layered structure, whereby a porous semiconductor film in contact with a semiconductor substrate is subjected to a heat treatment at a temperature above 1200° C. to form a compound semiconductor layered structure. Preferably, the present invention provides a process according to the second aspect of the invention, wherein said semiconductor substrate and said semiconductor film comprise a material selected from the group consisting of silicon carbide and gallium nitride. In a first embodiment, said semiconductor substrate and said semiconductor film comprise silicon carbide. Preferably, said silicon carbide comprises 4H-silicon carbide (4H—SiC). More preferably, said silicon carbide consists essentially of 4H-silicon carbide (4H—SiC). In a second embodiment, said semiconductor substrate and said semiconductor film comprise gallium nitride. Preferably, the inventive process according to the second aspect of the invention is used for the preparation of a compound semiconductor layered structure according to the first aspect of the invention. More specifically, the process according to the second aspect of the invention, comprises the steps of:
i. providing (a) a silicon carbide semiconductor substrate (1) having a bottom surface and a top surface, and (b) a silicon carbide semiconductor film (pre-2) having a porous bottom layer (pre-21), a porous core (pre-22) and a porous top layer (pre-23);
ii. bringing said bottom layer (pre-21) of said silicon carbide semiconductor film (pre-2) in direct contact with a top surface of said silicon carbide semiconductor substrate (1);
iii. pressing said silicon carbide semiconductor film (pre-2) and said silicon carbide semiconductor substrate (1) together at a pressure of 5 MPa to 100 MPa, and heating at a temperature between 1250° C. and 1750° C. under an inert atmosphere. Preferably, said pressing-heating step is performed for a period of 10 minutes to 8 hours at a pressure of 0.5 MPa to 10 MPa.

After the heating step, the silicon carbide film and the silicon carbide substrate are cooled to room temperature. It is found that the film adheres to the substrate. It is found that the porous bottom layer (pre-21) has undergone a reorganisation resulting from the pressure and temperature treatment to form a nonporous bottom layer (21) which adheres to the top surface of the silicon carbide semiconductor substrate (1). Preferably, the process according to the second aspect of the invention is suitable for preparing a compound semiconductor layered structure according to the first aspect of the invention.

Preferably, said porous semiconductor film is obtainable by an electrochemical porosification technique according to the experimental procedure described in Leitgeb, M. et al. Stacked Layers of Different Porosity in 4H SiC Substrates Applying a Photo-electrochemical Approach. J. Electrochem. Soc. 2017, 164 (12), E337, https://doi.org/10.1149/2.1081712jes; Leitgeb, M. et al. Metal Assisted Photochemical Etching of 4H Silicon Carbide. J. Phys. Appl. Phys. 2017, 50 (43), 435301, https://doi.org/10.1088/1361-6463/aa8942. Preferably, said porous semiconductor film in contact with a semiconductor substrate is subjected to a heat treatment at a temperature above 1400° C., above 1450° C., or even above 1500° C. and below 3000° C., below 2500° C., below 2000° C., below 1800° C., below 1700° C. or even below 1600° C. Preferably, said porous semiconductor film in contact with a semiconductor substrate is subjected to said heat treatment for a period of at least 10 minute, and more preferably at least 15 minutes, at least 20 minutes or at least 30 minutes. Preferably, said heat treatment is performed for a period of at most 8 hours, at most 4 hours, at most 2 hours or even at most 1 hour. Most preferably, said heat treatment is performed for a period of about 30 to 45 minutes. Alternatively, said heat treatment may consist of heating up said porous semiconductor film in contact with a semiconductor substrate to a predefined temperature and subsequently cooling down immediately to room temperature. Preferably, said semiconductor substrate is polished before contacting with said exfoliated semiconductor film.

Preferably, said semiconductor film is in direct contact with said semiconductor substrate. More specifically, said bottom layer of said semiconductor film is in direct contact with said top surface of said semiconductor substrate. The inventors have surprisingly found that a porous semiconductor film can be fusion-bonded directly onto a semiconductor substrate by heat treatment above a predefined temperature to yield a semiconductor double-layer with excellent properties, such as thermal and mechanical properties. Further growing a semiconductor overlayer onto said fusion-bonded film allows for a simple but reliable and economically advantageous process, whereas current processes are energy- and materials-intensive. Waste generation during to production process can be greatly reduced, contributing to an improved carbon dioxide footprint. In a preferred embodiment, said semiconductor substrate is a compound semiconductor substrate. In a preferred embodiment, said semiconductor film is a compound semiconductor film.

Preferably, the contacting surface of said semiconductor substrate, i.e. the surface which is contacted with said semiconductor film, has a surface roughness of at most 50 nm, as determined by Atomic Force Microscopy (AFM). A suitable AFM procedure for determining surface roughness of Si nanostructures is described by Nagase et al. Metrology of Atomic Force Microscopy for Si Nano-Structures. Jpn. J. Appl. Phys. 1995, 34, 3382, https://iopscience iop.org/article/10.1143/JJAP. 34. 3382/meta. More preferably, said contacting surface of said semiconductor substrate has a surface roughness of at most 20 nm, at most 10 nm, at most 5 nm, at most 2 nm, or even at most 1 nm. Most preferably, said contacting surface has a surface roughness of about 0.9 nm, 0.8 nm, 0.7 nm, 0.6 nm, 0.5 nm, 0.4 nm, 0.3 nm, 0.2 nm, or 0.1 nm, or any value there in between. The inventors found that, after fusion bonding of semiconductor film and substrate, adhesion of the semiconductor film to said semiconductor substrate improves as the surface roughness of the contacting surface of said semiconductor substrate is lower. Lower surface roughness of said contacting surface of said semiconductor substrate can be achieved by polishing, e.g. mechanical, chemo-mechanical, electrochemical or photoelectrochemical polishing.

Preferably, the present invention provides a process according to the second aspect of the invention, whereby said porous semiconductor film in contact with a semiconductor substrate is subjected to a heat treatment at a temperature of 1500° C. to 1600° C., preferably at a temperature above 1550° C., such as 1560° C., 1570° C., 1580° C., 1590° C. or 1600° C. Preferably, said porous semiconductor film in contact with a semiconductor substrate is subjected to a heat treatment under an inert atmosphere, such as helium, argon or hydrogen gas. In the context of the present invention, N₂ gas and O₂ gas are not considered inert gasses.

Preferably, the present invention provides a process according to the second aspect of the invention, whereby, during said heat treatment, said porous semiconductor film is in direct contact with a semiconductor substrate (1) and is pressed onto said semiconductor substrate (1) at a hot-press pressure of 5 MPa to 100 MPa. Such processes are easily conducted in a hot-press. Preferably, said heat treatment is performed at a hot-press pressure between 10 MPa and 75 MPa, more preferably between 15 MPa and 60 MPa, and even more preferably between 20 MPa and 50 MPa. Most preferably, said heat treatment is performed at a hot-press pressure of about MPa, 25 MPa, 30 MPa, 35 MPa, 40 MPa, 45 MPa or 50 MPa, or any pressure there in between. It was found that applying a pressure during the fusion bonding process improves the bonding characteristics of the obtained semiconductor layered structure.

Preferably, the present invention provides a process according to the second aspect of the invention, whereby said semiconductor film (pre-2) has a porous bottom layer (pre-21) having a porosity of 1 to 50%, as determined by SEM, a porous core (pre-22) having a porosity of 1.1 to 20%, as deter-mined by SEM and a porous top layer (pre-23) having a porosity of 1 to 50%, as determined by SEM, and whereby the ratio of porosity of said porous bottom layer (pre-21) to the porosity of said porous core (pre-22) is at least 1.1. Preferably, said ratio is at least 1.2, at least 1.3, at least 1.4 or even at least 1.5. Preferably, said ratio is at most equal to 5.

Preferably, the present invention provides a process according to the second aspect of the invention, further comprising the step of forming an epitaxial semiconductor overlayer on top of a semiconductor film.

In a third aspect, the present invention provides an electronic device for power electronics comprising a compound semiconductor layered structure according to the first aspect of the invention. Power electronic devices according to the third aspect of the invention are suitable for use in applications of converting DC solar power to AC power for domestic use, and regulating functions with regard to battery power in hybrid electric vehicles. The higher bandgap of the compound semiconductor layered structure according to the present invention allows for the electronics that use it to be smaller and operate much more energy-efficiently. Compound semiconductors according to the present invention function at higher temperatures, higher voltages, and higher frequencies than some prior art semiconductors. Furthermore, compound semiconductor layered structure according to the first aspect of the invention can advantageously be used a) as interface layer in SAW devices between piezoelectric layer and silicon substrate, and b) in MEMS, for fabrication of cantilevers or membranes from SiC on Si substrate for harsh environmental applications.

### EXAMPLE

The following examples are intended to further clarify the present invention, and are nowhere intended to limit the scope of the present invention.

### Example 1

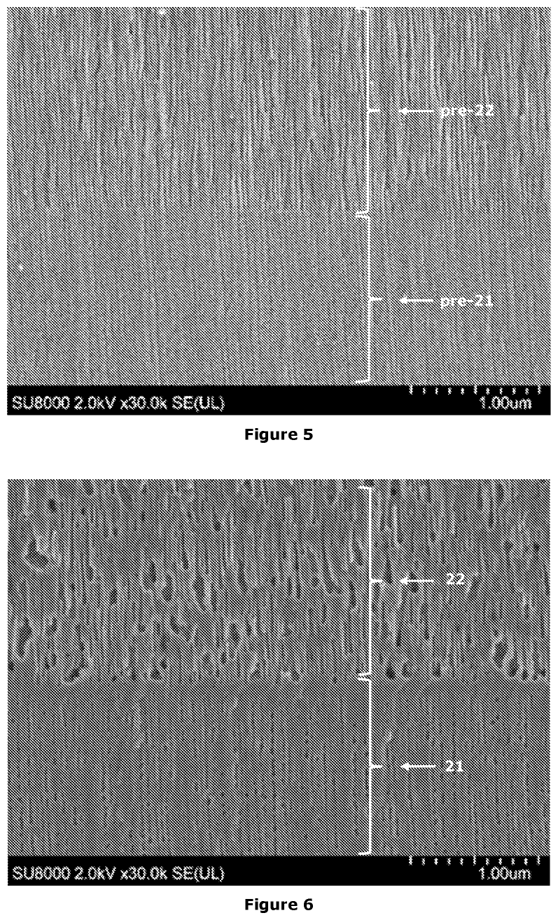

A polycrystalline silicon carbide substrate 1 is fused to a thin 16 μm single crystalline porous silicon carbide foil 2 by fusion bonding. The thin porous foil is obtained by utilizing a combination of metal assisted photochemical etching (MAPCE) and photo-electrochemical etching (PECE) according to the experimental procedure described in Leitgeb, M. et al. Stacked Layers of Different Porosity in 4H SiC Substrates Applying a Photoelectrochemical Approach. J. Electrochem. Soc. 2017, 164 (12), E337, https://doi.org/10.1149/2.1081712jes; Leitgeb, M. et al. Metal Assisted Photochemical Etching of 4H Silicon Carbide. J. Phys. Appl. Phys. 2017, 50 (43), 435301, https://doi.org/10.1088/1361-6463/aa8942. By varying the applied voltage (8.5 to 11.5 V) in the procedures in reference, the skilled person can obtain a predetermined degree of porosity, as a higher voltage leads to a higher degree of porosity (see FIG. 5). By further raising the applied voltage above a predetermined threshold level, a porous film is exfoliated from the mother substrate.

This procedure can be carried out multiple times, which allows the preparation of multiple porous films from a given 4H—SiC mother substrate. The characteristics of the foils are easily and accurately controlled. The initial MAPCE step just enhances the initial pore formation for the very first PECE process. Typically, the roughness of the mother substrate surface after exfoliation of a porous layer is approximately 100 nm which sufficiently aides pore formation in the beginning of PECE. Therefore, MAPCE is not necessary after the first exfoliation procedure.

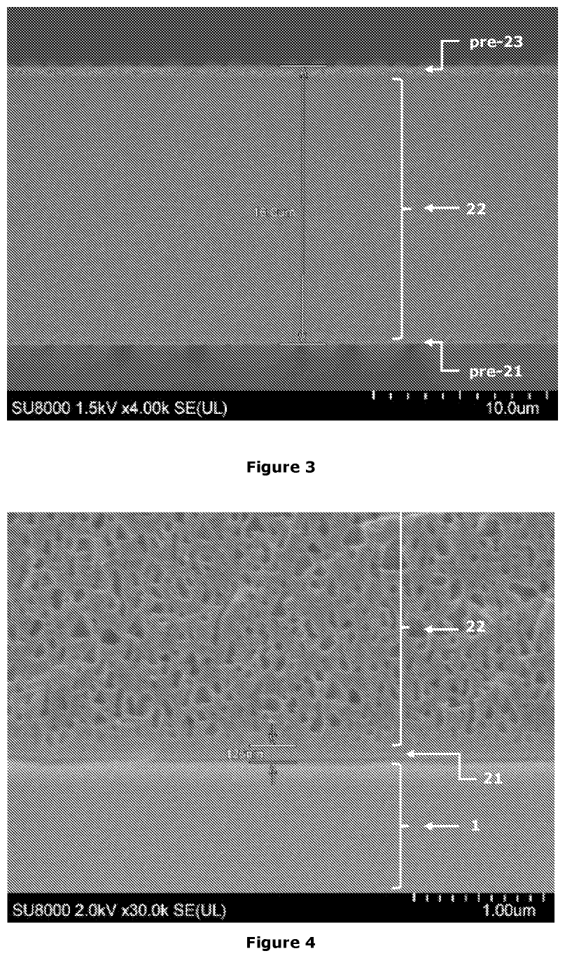

The obtained porous film is placed on the top surface of a polycrystalline SiC substrate and subjected to a hot-press heat treatment at a temperature of 1600° C. and a pressure of about 35 MPa under an inert He gas atmosphere (1 atm). It is contemplated that during such heat treatment, the high porosity bottom layer of the porous film enhances local self-diffusion and subsequently causes densification and fusion bonding of the porous foil to the polycrystalline SiC substrate. This is depicted in FIGS. 3 and 4. Furthermore, during the heat treatment all the pores in the semiconductor substrate reorganize due to minimization of surface energy. Consequently, the pores in the porous film are encapsulated within a single crystalline matrix having no connection to the outward atmosphere, as shown in FIGS. 3 and 4.

A compound semiconductor layered structure is obtained consisting of a polycrystalline SiC substrate and a semiconductor film on top of said semiconductor substrate. Subsequently, a single crystalline epitaxial layer 3 of 4H—SiC is deposited onto said semiconductor film by chemical vapor deposition. Other methods of deposition can be contemplated.

### Example 2

A polycrystalline silicon carbide substrate 1 is fused to a thin 34 μm single crystalline porous silicon carbide foil 2 by fusion bonding in a hot-press.

The thin porous foil is obtained as described in Example 1. The obtained porous film is placed on the top surface of a polished polycrystalline SiC substrate and subjected to a heat treatment at a temperature of 1600° C. under an inert Ar gas atmosphere (1 atm) using hot-press equipment to apply a pressure of about 35 MPa to the double-layer. All other process parameters are as described in Example 1.

A compound semiconductor layered structure is obtained consisting of a polycrystalline SiC substrate and a semiconductor film on top of said semiconductor substrate. Subsequently, a single crystalline epitaxial layer 3 of 4H—SiC is deposited onto said semiconductor film by chemical vapor deposition. Other methods of deposition can be contemplated.

### Example 3

A polycrystalline gallium nitride substrate is fused to a thin 18 μm single crystalline porous gallium nitride foil by fusion bonding in a hot-press.

The thin porous gallium nitride foil is obtained in a manner similar as described in Example 1. The obtained porous film is placed on the top surface of a polished polycrystalline gallium nitride substrate and subjected to a heat treatment at a temperature of 1550° C. under an inert He gas atmosphere using hot-press equipment to apply a pressure of about 35 MPa to the double-layer. All other process parameters are as described in Example 1.

A compound semiconductor layered structure is obtained consisting of a polycrystalline gallium nitride substrate and a semiconductor film on top of said semiconductor substrate. Subsequently, a single crystalline epitaxial layer of gallium nitride is deposited onto said semiconductor film by chemical vapor deposition.

### Example 4

A polycrystalline aluminium nitride substrate is fused to a thin 18 μm single crystalline porous gallium nitride foil by fusion bonding in a hot-press. The thin porous gallium nitride foil is obtained in a manner similar as described in Example 1. The obtained porous film is placed on the top surface of a polished polycrystalline aluminium nitride substrate and subjected to a heat treatment at a temperature of 1550° C. under an inert He gas atmosphere (1 atm) using hot-press equipment to apply a pressure of about 35 MPa to the double-layer. All other process parameters are as described in Example 1.

A compound semiconductor layered structure is obtained consisting of a polycrystalline aluminium nitride substrate and a gallium nitride film on top of the aluminium nitride substrate. Subsequently, a single crystalline epitaxial layer of gallium nitride is deposited onto said semiconductor film by chemical vapor deposition.

### Example 5

A method according to Example 4 whereby the polycrystalline aluminium nitride substrate is replaced by a composite ceramic material, whereby said ceramic material has a coefficient of thermal expansion which is matched to GaN.

1-15. (canceled)

16. A compound semiconductor layered structure comprising:
i. a silicon carbide semiconductor substrate having a bottom surface and a top surface; and
ii. a silicon carbide semiconductor film on top of said silicon carbide semiconductor substrate, said silicon carbide semiconductor film comprising a nonporous bottom layer, a porous core, and a nonporous top layer, whereby said bottom layer of said silicon carbide semiconductor film is in direct contact with said top surface of said silicon carbide semiconductor substrate.

17. Compound semiconductor layered structure according to claim 16, wherein said silicon carbide semiconductor substrate comprises a polycrystalline material.

18. Compound semiconductor layered structure according to claim 16, wherein said porous core has a porosity of 1 to 50%, as determined by SEM.

19. Compound semiconductor layered structure according to claim 18, wherein said porous core has a porosity of at most 15%, as determined by SEM.

20. Compound semiconductor layered structure according to claim 16, wherein said bottom layer and/or said top layer of said silicon carbide semiconductor film have a thickness of at least 10 nm and at most 250 nm.

21. Compound semiconductor layered structure according to claim 16, wherein said silicon carbide semiconductor film has a thickness of 0.5 μm to 40 μm.

22. Compound semiconductor layered structure according to claim 16, further comprising a semiconductor overlayer having a bottom surface layer and a top surface layer, whereby said bottom surface layer of said semiconductor overlayer is in direct contact with said top layer of said silicon carbide semiconductor film.

23. Compound semiconductor layered structure according to claim 22, wherein said semiconductor overlayer comprises one or more materials selected from the group consisting of gallium arsenide, gallium nitride, silicon germanium, and silicon carbide.

24. Process for preparing a compound semiconductor layered structure, comprising the steps of:
i. providing (a) a silicon carbide semiconductor substrate having a bottom surface and a top surface, and (b) a silicon carbide semiconductor film (pre-2) having a porous bottom layer (pre-21), a porous core (pre-22) and a porous top layer (pre-23);
ii. bringing said bottom layer (pre-21) of said silicon carbide semiconductor film (pre-2) in direct contact with a top surface of said silicon carbide semiconductor substrate;
iii. pressing said silicon carbide semiconductor film (pre-2) and said silicon carbide semiconductor substrate together at a pressure of 5 MPa to 100 MPa, and heating at a temperature between 1250° C. and 1750° C. under an inert atmosphere at a pressure of 0.5 MPa to 10 MPa.

25. Process according to claim 24, whereby said silicon carbide semiconductor substrate provided in step i. has a surface roughness of at most 10 nm, as determined by Atomic Force Microscopy (AFM).

26. Process according to claim 24, whereby said porous silicon carbide semiconductor film in contact with a semiconductor substrate is subjected to a heat treatment at a temperature of 1450° C. to 1650° C.

27. Process according to claim 24, whereby said inert atmosphere comprises helium or argon.

28. Process according to claim 24, whereby said silicon carbide semiconductor film (pre-2) has a porous bottom layer (pre-21) having a porosity of 1 to 50%, as determined by SEM, a porous core (pre-22) having a porosity of 1.1 to 20%, as determined by SEM and a porous top layer (pre-23) having a porosity of 1 to 50%, as determined by SEM, and whereby the ratio of porosity of said porous bottom layer (pre-21) to the porosity of said porous core (pre-22) is at least 1.1.

29. Process according to claim 24, further comprising the step of growing an epitaxial semiconductor overlayer on top of a silicon carbide semiconductor film.

30. Compound semiconductor layered structure obtainable by the process according to claim 24.
